(19) United States
(12) Patent Application Publication
(10) Pub. No.: US 2018/0183429 A1
(43) Pub. Date: Jun. 28, 2018

(54) INTEGRATED SERIES SCHOTTKY DIODE RECTIFIER

(71) Applicant: SIRECTIFIER ELECTRONIC CO., LTD., New Taipei City (TW)

(72) Inventors: Wen-Pin CHEN, New Taipei City (TW); Kuo-Tung LEE, New Taipei City (TW)

(21) Appl. No.: 15/392,467

(22) Filed: Dec. 28, 2016

(51) Int. Cl. H03K 17/16; H01L 23/495; H01L 25/07; H01L 29/872; H01L 23/29

(52) U.S. Cl. CPC H03K 17/16; H01L 23/49568; H01L 23/293; H01L 29/872; H01L 25/072

(57) ABSTRACT

An integrated series Schottky diode rectifier having the characteristics of high reverse voltage resistance, ease of fabrication, small size, high yield rate, automated fabrication applicability and low manufacturing cost is disclosed to include multiple lead frames, multiple Schottky diode chips mounted on the lead frames and connected in series, first conductor connected to the positive electrode of first Schottky diode chip, second conductor connected to the positive electrode of each of other Schottky diode chip and bridged onto the lead frame that carries the previous Schottky diode chip, electrode pin set including positive pin connected to first conductor at first Schottky diode chip, negative pin connected to negative electrode of last Schottky diode chip and external pin connected in series between second conductors of each two adjacent Schottky diode chips, and resin package body molded on lead frames and wrapped about Schottky diode chips and electrode pin set.

### BACKGROUND OF THE INVENTION

### 1. Field of the Invention

The present invention relates to Schottky diode rectifier and more particularly, to an integrated series Schottky diode rectifier, which is made by connecting a plurality of Schottky diodes in series, having the characteristics of high reverse voltage resistance, ease of fabrication, small size, high yield rate, automated fabrication applicability and low manufacturing cost.

### 2. Description of the Related Art

With fast development of electronic technology and the trend of the development of electronic products toward the design with light, thin, short and small characteristics, small-sized electronic products have been continuously created. And almost all components in circuit boards for advanced electronic products are manufactured using the integrated circuit manufacturing process. In the application of integrated circuit type electronic components, it is necessary to consider more factors, such as breakdown voltage, noise immunity, and mutual interference of internal components. Especially in the application of power components on a circuit board, the factor of voltage and current tolerance is the focus of consideration. When the voltage and current are excessively high, the integrated circuit can be overheated and burned out due to insufficient withstand voltage. If the withstand voltage is sufficient, the circuit characteristics between components within the integrated circuit must be taken into account to ensure the overall effect.

Further, among the various power components of electronic products (such as power supply device, motor drive, etc.), diodes are the mostly widely used components. A diode is a two-terminal electronic component that conducts primarily in one direction and breaks down in the reversed direction. Therefore, diodes are intensively used in switching power supply circuits, frequency converter circuits and driver circuits for high frequency, low voltage, high current rectification to provide stabilized DC output. Such diodes are generally referred to as rectifier diodes, and widely used in consumer electronics, communications, automotive, aerospace, medical and other fields.

As it is the market trend to create integrated circuit type rectifier diodes, there are manufacturers created the design of packaging two diodes in one integrated circuit and installing one single integrated diode in a circuit board to reduce the manufacturing cost.

Further, non-linear loads such as rectifiers, switching power supply circuits are commonly seen in power supply devices. Since non-linear loads can convert the inputted AC current since wave from a power transmission system into other waveforms, in addition to the original power supply frequency (fundamental frequency), there will be many high-frequency harmonic currents in the input current, resulting in a large phase difference between the input current and voltage to decrease the power factor (the ratio of working power to apparent power, PF). Further, due to low utilization of the effective power in the power supply circuit, power loss will be increased. Therefore, the common practice in the industry is to add a power factor correction circuit (PFC) to the power supply circuit. This measure not only can improve the stability of power supply. Further, after power factor correction, the apparent power is lowered, and therefore, it improves the power factor of the power supply circuit, reduces frequency harmonic pollution and also improves power supply quality and utilization. Nowadays, every country around the world pays more attention to the subjects of global warming and energy saving. In order to fabricate products in response to the needs of carbon reduction, requirements for power supply efficiency and quality have become more and more critical so as to save energy and electricity expense. Therefore, a boost-type power factor correction circuit is generally used in the front stage of a power supply device. Since the inputted inductor current at the continuous conduction mode (CCM) is not reduced to zero, the inductance voltage variation is small, the components in the power supply circuit can have lower conduction losses, less electromagnetic interference and a smaller input filter to prevent the transmission system from giving a high frequency transient impact current to the power circuit, and thus, the product can be in line with power factor requirements and the international harmonic current specifications. Further, since the power circuit has high reverse voltage (such as 600V) and high frequency (such as greater than 100 KHz) operating characteristics, the power switch is not conducted at zero inductor current, so it needs to use a rectifier diode having a high withstand voltage and fast recovery speed to reduce switching losses. Regular switching power supply circuits commonly use a single high-voltage 600V or over 600V fast recovery diodes (FRD) or silicon carbide (SiC) Schottky diode (SBD) for rectification. However, the reverse recovery time (trr) of a fast recovery diode is not fast enough, and the reverse recovery charge (Qrr) of a fast recovery diode is not small enough, therefore, the rectification efficiency of a fast recovery diode is not good enough (power factor is not high enough), leading to large loss, ripple, noise interference problems. Further, a silicon carbide (SiC) Schottky diode (SBD) has the advantages of fast reverse recovery speed and high rectification efficiency; however, due to the disadvantages of high cost and large forward conduction voltage loss, silicon carbide (SiC) Schottky diode (SBD) is not commonly used.

In regular rectifier diode designs, connecting diode chips in series can achieve the purpose of adding reverse withstand voltage; connecting diode chips in parallel can achieve the purpose of adding rated current. However, in the actual application of rectifier diode in the past few years, the parallel method is to use a symmetrical lead frame structure, and then to bond two diode chips to the surface of the lead frame for enabling each diode chip to be electrically connected to a respective pin through a lead wire or by soldering, and to mold a resin package body (for example, epoxy resin) on the lead frame, the lead wires, the pins and the diode chips, enabling the top and output end of the lead frame and the input ends of the pins to be exposed to the outside of the resin package body. The design of symmetrical lead frame structure for parallel application has a simple structure, facilitating processing and automated fabrication.

For series connection, under the use of a conventional symmetrical lead frame, two diode chips must be bonded to the surface of the lead frame in a reversed manner so that the lead wire bonding and resin packaging can be followed up. This procedure is complicated, lacking of quantitative production and reliability. Therefore, the industry rarely uses the series diode chip connection method for mass production. Further in actual application, the non-uniformity of electrical characteristics among multiple diode chips in a series diode chip connection structure can cause static pressure unbalance and dynamic voltage change in end products under different conditions, leading to withstand voltage differences between the series-connected diode chips and device failure. For example, in the application of a total reverse voltage 400V power supply circuit that comprises two 300V diode chips connected in series, due to pre-power and post-power, the two diode chips cannot equally share equivalent 200V voltage. If one diode chip withstands a reverse working voltage over 300V, this diode chip can be broken down and failed. Therefore, the prior art method of using series-connected diode chips to improve reverse withstand voltage is not reliable. According to conventional techniques, it is not practical to apply the method of connecting the diode chips in series to various power supply circuit designs. An improvement in this regards is desired.

### SUMMARY OF THE INVENTION

The present invention has been accomplished under the circumstances in view. It is therefore one object of the present invention to provide an integrated series Schottky diode rectifier, which has the characteristics of high reverse voltage resistance, ease of fabrication, small size, high yield rate, automated fabrication applicability and low manufacturing cost.

To achieve this and other objects of the present invention, the integrated series Schottky diode rectifier a plurality of lead frames, a plurality of Schottky diode chips, an electrode pin set and a resin package body. The Schottky diode chips are mounted on the lead frames and electrically connected in series. Each Schottky diode has a negative electrode located on a back side thereof and electrically connected to the at least two lead frames, and a positive electrode located at an opposing front side thereof. The positive electrode of the first Schottky diode chip has a first conductor bonded thereto. The positive electrode of each of the other Schottky diode chips has a second conductor bonded thereto. The second conductor at each Schottky diode is bridged onto the lead frame that carries the previous the at least two Schottky diode chips. The electrode pin set comprises a positive pin connected to the first conductor at the first Schottky diode chip, a negative pin connected to the negative electrode of the last Schottky diode chip, and an external pin connected in series between the second conductors of each two adjacent Schottky diode chips. The resin package body is molded on the lead frames and wrapped about the Schottky diode chips and the electrode pin set.

According to another aspect of the present invention, at least two Schottky diode chips are mounted on each of at least two lead frames, and the positive pin and negative pin of the electrode pin set are respectively electrically connected to the positive and negative electrodes of the series of Schottky diode chips and the external pin electrically connected in series to the Schottky diode chips between the positive pin and the negative pin to balance the voltage or to form a voltage regulation pin. Thus, the positive pin, the negative pin and the external pin can be used to test the reverse withstand voltage of each Schottky diode chip. Further, the electrode pin set can be connected to a buffer circuit of a circuit board, enabling the positive pin, the negative pin and the external pin to be connected to the respective Schottky diode chips in parallel. The buffer circuit can be based on one or multiple resistors, one or multiple capacitors, or a series of resistor and capacitor for lowering the working voltage of the Schottky diode chip that receives an overvoltage, avoiding Schottky diode chip failure due to unbalanced reverse voltage, eliminating voltage balancing and stability problems in different circuit designs, and providing great flexibility and reliability.

According to still another aspect of the invention, when using the integrated series Schottky diode rectifier of the present invention in the switching power supply circuit of a power supply device, two Schottky diode chips of highly consistent characteristics can be connected in series to stabilize and divide a high reverse voltage. The reasonable resistance value and capacitance value for the buffer circuit can be calculated according to the electrical characteristics of the first Schottky diode chip. In installation, the electrode pin set is connected to the buffer circuit to increase voltage tolerance, avoiding breakdown failure upon a high voltage. Thus, the reverse voltage each Schottky diode chip receives is just about one half of the reverse voltage a single boost-type diode receives during operation. Thus, the Schottky diode chip having a relatively lower reverse withstand voltage will have a relatively shorter reverse recovery time and a relatively smaller reverse recovery loss. Through the voltage division treatment of the series connected Schottky diode chips, the power factor correction circuit can accelerate the switching speed, reduce power loss and improve current rectification efficiency, thereby improving the switching power factor and reducing harmonic pollution to ensure high-quality power supply. Thus, the integrated series Schottky diode rectifier of the present invention greatly improves the utilization of power supply to reduce the cost, and is practical for high-frequency, high-voltage and large current switching power supply applications and more in line with energy-saving and efficient development needs.

### BRIEF DESCRIPTION OF THE DRAWINGS

FIG. 1 illustrates the architecture of an integrated series Schottky diode rectifier in accordance with the present invention.

FIG. 2 illustrates two Schottky diodes connected in series in accordance with the present invention.

FIG. 3 illustrates one Schottky diode mounted on one respective lead frame and the electrode pin set connected to the series-connected Schottky diodes.

FIG. 4 is a schematic drawing illustrating two Schottky diodes connected in series in accordance with the present invention.

FIG. 5 is a schematic drawing illustrating three Schottky diodes connected in series in accordance with the present invention.

FIG. 6 is a schematic drawing illustrating two Schottky diodes connected in series and a two-resistor type buffer circuit connected to the series of Schottky diodes in accordance with the present invention.

FIG. 7 is a schematic drawing illustrating three Schottky diodes connected in series and a three-resistor type buffer circuit connected to the series of Schottky diodes in accordance with the present invention.

FIG. 8 is a schematic drawing illustrating two Schottky diodes connected in series and a two-capacitor type buffer circuit connected to the series of Schottky diodes in accordance with the present invention.

FIG. 9 is a schematic drawing illustrating three Schottky diodes connected in series and a three-capacitor type buffer circuit connected to the series of Schottky diodes in accordance with the present invention.

FIG. 10 is a schematic drawing illustrating two Schottky diodes connected in series and a resistor-capacitor type buffer circuit connected to the series of Schottky diodes in accordance with the present invention.

FIG. 11 is a reverse recovery time and reverse recovery charge waveform chart obtained from a test made on an integrated series Schottky diode rectifier in accordance with the present invention under the room temperature.

FIG. 12 is a reverse recovery time and reverse recovery charge waveform chart obtained from a test made on an integrated series Schottky diode rectifier in accordance with the present invention under a high temperature.

FIG. 13 is a reverse recovery time and reverse recovery charge waveform chart obtained from a test made on a prior art fast recovery diode-based rectifier under the room temperature.

FIG. 14 is a reverse recovery time and reverse recovery charge waveform chart obtained from a test made on the same prior art fast recovery diode-based rectifier under a high temperature.

FIG. 15 is a reverse recovery time and reverse recovery charge waveform chart obtained from a test made on another design of prior art fast recovery diode-based rectifier under the room temperature.

FIG. 16 is a reverse recovery time and reverse recovery charge waveform chart obtained from a test made on the same another design of prior art fast recovery diode-based rectifier under a high temperature.

### DETAILED DESCRIPTION OF THE PREFERRED EMBODIMENT

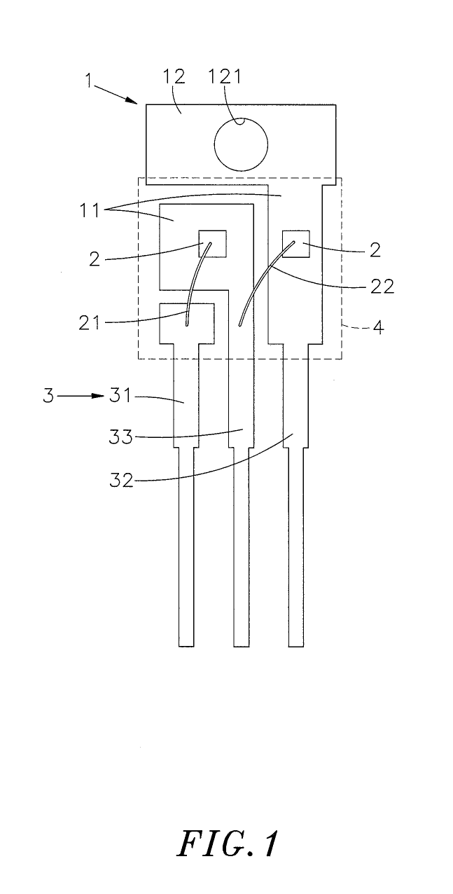

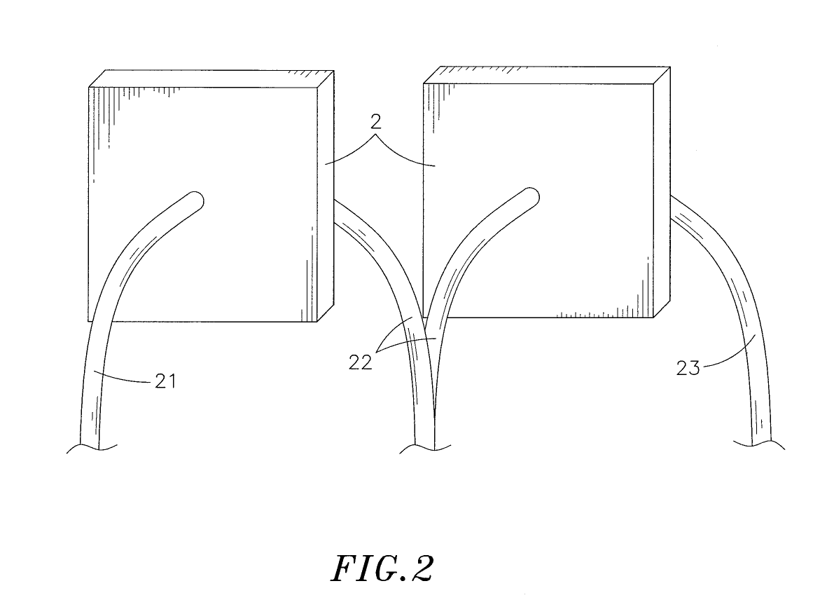

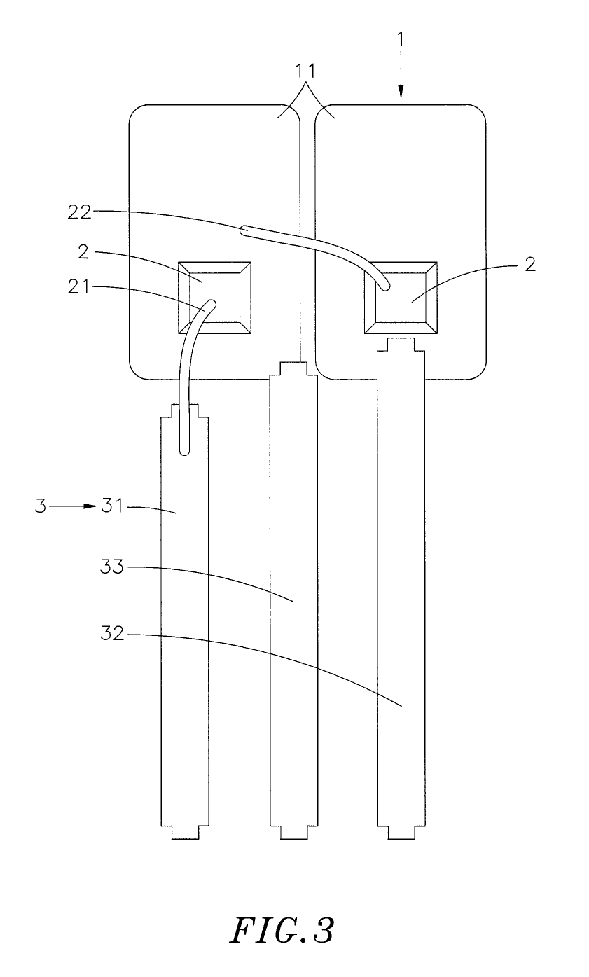

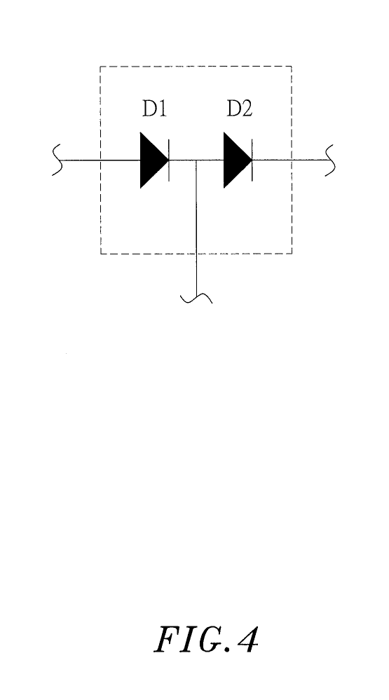

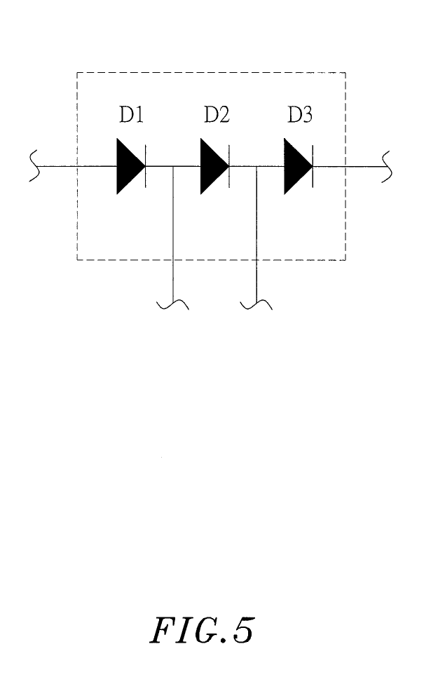

Please refer to FIGS. 1-5, where FIG. 1 illustrates the architecture of an integrated series Schottky diode rectifier in accordance with the present invention; FIG. 2 illustrates two Schottky diodes connected in series in accordance with the present invention; FIG. 3 illustrates one Schottky diode mounted on one respective lead frame and the electrode pin set connected to the series-connected Schottky diodes; FIG. 4 is a schematic drawing illustrating two Schottky diodes connected in series in accordance with the present invention; FIG. 5 is a schematic drawing illustrating three Schottky diodes connected in series in accordance with the present invention. As illustrated, the integrated series Schottky diode rectifier of the invention comprises at least two lead frames 1, a plurality of Schottky diode chips 2 numbered in proper order from the first to the last, an electrode pin set 3 and a resin package body 4.

Each lead frame 1 comprises a flat substrate 11 (metal plate made of copper or copper alloy), a copper radiation fin 12 located at a top side of the flat substrate 11 and having a width larger than the flat substrate 11, and a circular through hole 121 located on the radiation fin 12.

Each Schottky diode chip 2 has a positive electrode and a negative electrode respectively located on opposing front and back sides thereof. The negative electrodes of the Schottky diode chips 2 are respectively bonded to the surface of the flat substrates 11 of the lead frames 1 with a solder material or conductive adhesive. The positive electrode of the first Schottky diode chip 2 has a first conductor 21 bonded thereto with a solder material or conductive adhesive. The positive electrode of other Schottky diode chip 2 has a second conductor 22 bonded thereto with a solder material or conductive adhesive. The second conductor 22 of each Schottky diode chip 2 is bonded with a solder material or conductive adhesive to the lead frame 1 on which the previous Schottky diode chip 2 is located to achieve connection in series. The negative electrode of the last Schottky diode chip 2 has a third conductor 23 bonded to the negative electrode thereof with a solder material or conductive adhesive.

The electrode pin set 3 comprises a positive pin 31, a negative pin 32 and at least one external pin 33 arranged between the positive pin 31 and the negative pin 32. The positive pin 31 is bonded to the first conductor 21 of the first Schottky diode chip 2 with a solder material or conductive adhesive. The negative pin 32 is bonded to the third conductor 23 at the negative electrode of the last Schottky diode chip 2 with a solder material or conductive adhesive. Alternatively, the third conductor 23 can be eliminated, enabling the negative pin 32 at the lead frame 1 that carries the last Schottky diode chip 2 to be directly or indirectly extended to the outside. Further, the external pin 33 is bonded in series between the second conductors 22 of two adjacent Schottky diode chips 2 with a solder material or conductive adhesive, and can be directly or indirectly extended to the outside. Other alternative arrangements or modifications can be selectively used according to actual application requirements without departing the spirit of the invention.

The resin package body 4 is selective from epoxy resin or other plastic resin and directly molded on the lead frame 1 to wrap about the Schottky diode chips 2 and the electrode pin set 3 to form an electrically insulative body. Further, the free ends of the positive pin 31, the negative pin 32 and the external pin 33 of the electrode pin set 3 are extended out of the resin package body 4.

In this embodiment, the Schottky diode chips 2 refer to silicon (Si) substrate-based, unencapsulated silicon Schottky diodes; further, 2 or 3 (see FIG. 4 and FIG. 5) Schottky diode chips 2 (such as D1, D2, D3) are respectively bonded to the one respective lead frame 1 with the positive electrode of the first Schottky diode chip 2 connected to the positive pin 31 of the electrode pin set 3 through the first conductor 21 (such as copper or aluminum bonding wire, overlapped copper frame), and the negative electrode of the last Schottky diode chip 2 directly bonded to the negative pin 32 or through the third conductor 23; the positive electrode of the last Schottky diode chip 2 of the series of Schottky diode chips 2 is connected to the previous lead frame 1 and the negative electrode of the Schottky diode chip 2 in series using the second conductor 22; the resin package body 4 is then molded on the lead frame 1 to wrap about the Schottky diode chips 2 and the electrode pin set 3, allowing the radiation fin 12 of the lead frame 1 and the positive pin 31, the negative pin 32 and external pin 33 of the electrode pin set 3 to be exposed to the outside of the resin package body 4. This integrated series Schottky diode rectifier greatly enhances static pressure balance of the series of Schottky diode chips 2 and enables the Schottky diode chips 2 to withstand reverse voltage evenly. Thus, an integrated series Schottky diode rectifier in accordance with the present invention has the advantages of low cost and high reverse voltage resistance. When compared to fast recovery diodes or silicon carbide Schottky diodes, low-voltage silicon Schottky diode has the characteristics of short reverse recovery time and low reverse recovery loss, and thus, using low-voltage silicon Schottky diodes for creating an integrated series Schottky diode rectifier can save much the cost. Further, the integrated series Schottky diode rectifier of the present invention requires less installation space. Multiple silicon Schottky diodes having consistency in electrical characteristics can be used and connected in series to create an integrated series Schottky diode rectifier in accordance with the present invention, providing the advantages of ease of fabrication, small size, high yield rate, automated fabrication and low manufacturing cost.

In the above-described integrated series Schottky diode rectifier, at least two Schottky diode chips 2 are mounted on each of at least two lead frames 1, and the positive pin 31 and the negative pin 32 of the electrode pin set 3 are respectively electrically connected to the positive and negative electrodes of the series of Schottky diode chips 2 and the external pin 33 electrically connected in series to the Schottky diode chips 2 between the positive pin 31 and the negative pin 32 to balance the voltage or to form a voltage regulation pin. Thus, the positive pin 31, the negative pin 32 and the external pin 33 can be used to test the reverse withstand voltage of each Schottky diode chip 2. Further, resistors, capacitors and other electronic components can be mounted in the circuit according to actual requirements, enabling the external pin 33 to be electrically connected to an external balancing resistor, or an external variable resistor or capacitor for balancing the dynamic voltage variation of the Schottky diode chips 2, avoiding failure of the Schottky diode chips 2 due to unbalanced reverse voltage, eliminating voltage balancing and stability problems in different circuit designs, and providing great flexibility and reliability. Thus, the integrated series Schottky diode rectifier of the invention realizes the rationality, convenience, applicability and long-term reliability of series connection, minimizes space requirement and realizes high power density design and market requirements for a product having light, thin, short, small characteristics. This design of integrated series Schottky diode rectifier of the invention can be applied to all the different application fields, and can meet energy-saving and efficient development needs.

The integrated series Schottky diode rectifier of the invention utilizes the series voltage divider principle (series connection increase in equivalent resistance) and the characteristic that the front side and rear side power supply in a power supply circuit can lead to a different voltage at the boost type diode, thus, the two Schottky diode chips 2 (silicon Schottky diode) of relatively lower reverse withstand voltage and faster reverse recovery time can be connected in series, equivalent to voltage series (for example, D1+D2=300V+300V or 350V+350V). Further, according to different voltage distribution, a high front low back series connection or low front high back series connection (for example D1+D2=350V+250V) can be adopted. Subject to the characteristics of fast reverse recovery time and short reverse recovery charge of the Schottky diodes, the integrated series Schottky diode rectifier of the invention improves the rectification efficiency of the power factor correction circuit, and lowers the ripple and noise interference. Since the silicon Schottky diodes are relatively cheap, the integrated series Schottky diode rectifier of the invention has the advantage of low cost and is more in line with economic efficiency and high efficiency needs

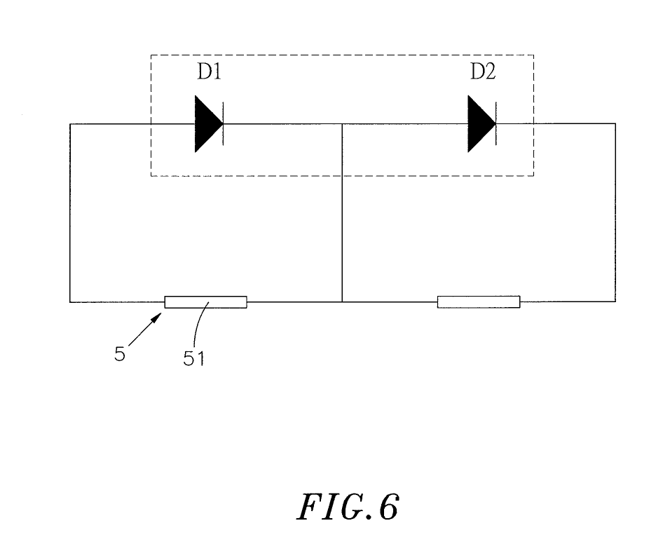

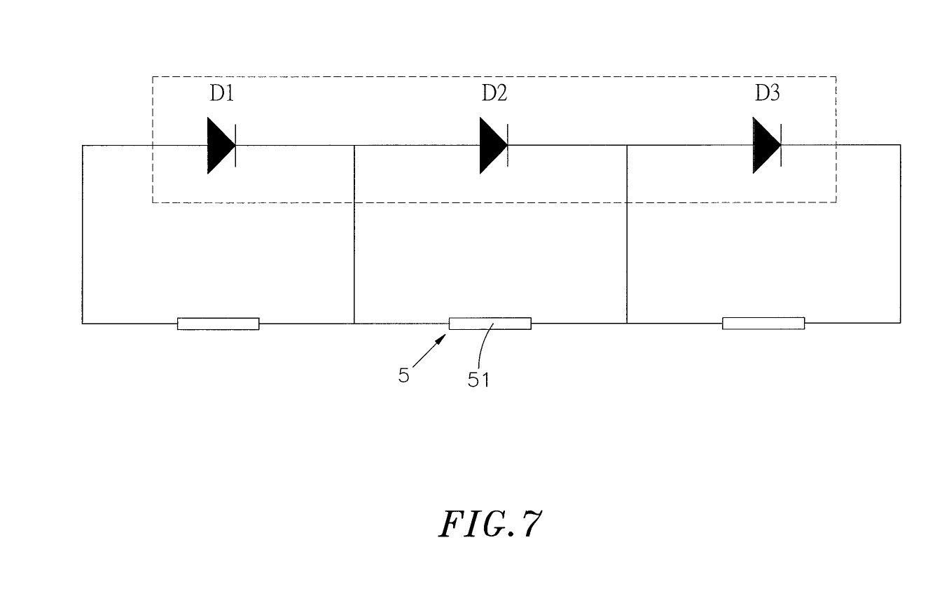

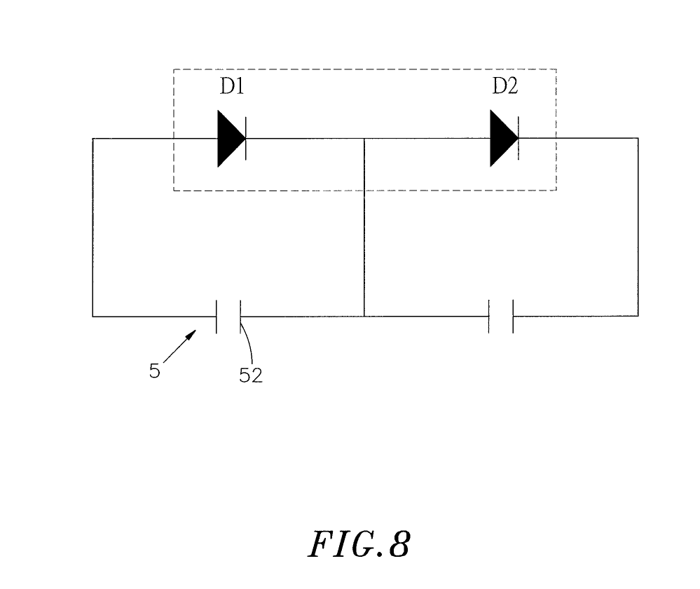

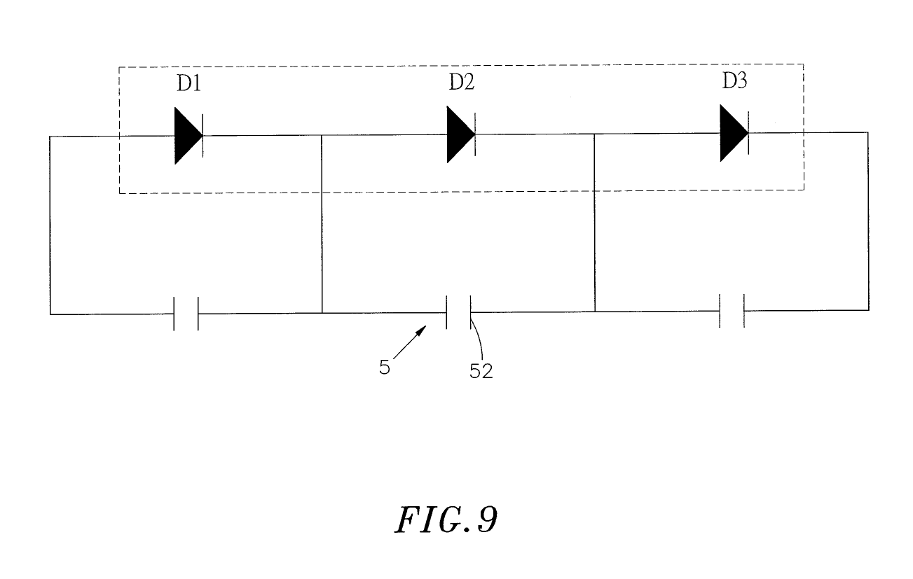

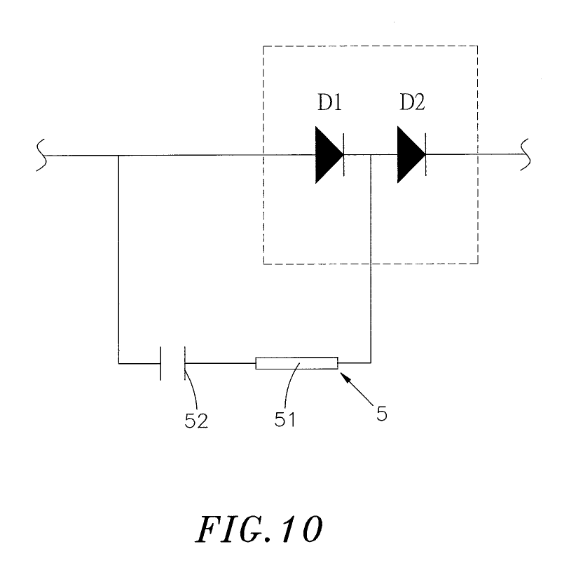

Please refer to FIGS. 6-10, where FIG. 6 is a schematic drawing illustrating two Schottky diodes connected in series and a two-resistor type buffer circuit connected to the series of Schottky diodes in accordance with the present invention; FIG. 7 is a schematic drawing illustrating three Schottky diodes connected in series and a three-resistor type buffer circuit connected to the series of Schottky diodes in accordance with the present invention; FIG. 8 is a schematic drawing illustrating two Schottky diodes connected in series and a two-capacitor type buffer circuit connected to the series of Schottky diodes in accordance with the present invention; FIG. 9 is a schematic drawing illustrating three Schottky diodes connected in series and a three-capacitor type buffer circuit connected to the series of Schottky diodes in accordance with the present invention; FIG. 10 is a schematic drawing illustrating two Schottky diodes connected in series and a resistor-capacitor type buffer circuit connected to the series of Schottky diodes in accordance with the present invention. As illustrated, the integrated series Schottky diode rectifier enables the electrode pin set 3 to be connected to a circuit board that carries a snubber circuit 5. Through at least two kinds of pins among the positive pin 31, the negative pin 32 and the external pin 33, the snubber circuit 5 is connected in parallel to the Schottky diode chips 2 at the corresponding lead frame 1. Further, the number of location of the components of the snubber circuit 5 can be determined according to the reverse voltage measured at each Schottky diode chip 2 in actual application, thereby adjusting the operating voltage of the Schottky diode chip 2 that responses to the snubber circuit 5, for example, the Schottky diode chip 2 of overvoltage. Further, the snubber circuit 5 comprises at least one resistor 51, or at least one capacitor 52, or the resistor 51 and the capacitor 52 connected in series for voltage balancing regulation.

In one example of the present invention, the snubber circuit 5 comprises at least one resistor 51. The resistance value of each resistor 51 matches the working voltage of each Schottky diode chip 2. In the example shown in FIG. 6, the two Schottky diode chips 2 are connected in series; the electrode pin set 3 comprises the one external pin 33; the snubber circuit 5 comprises a first resistor 51 that has two opposite ends thereof respectively connected to the positive pin 31 and the external pin 33, and a second resistor 51 that has two opposite ends thereof respectively connected to the external pin 33 and the negative pin 32. In the example shown in FIG. 7, the three Schottky diode chips 2 are connected in series; the electrode pin set 3 comprises the two external pins 33; the first resistor 51 of the snubber circuit 5 that has two opposite ends thereof respectively connected to the positive pin 31 and the first external pin 33, the second resistor 51 that has two opposite ends thereof respectively connected to the first and second external pins 33, and a third resistor 51 that has two opposite ends thereof respectively connected to the second external pin 33 and the negative pin 32.

In an alternate form of the present invention, the snubber circuit 5 comprises at least one capacitor 52. The capacitance value of each capacitor 52 matches the working voltage of each Schottky diode chip 2. In one example as shown in FIG. 8, the two Schottky diode chips 2 are connected in series; the electrode pin set 3 comprises the one external pin 33; the snubber circuit 5 comprises a first capacitor 52 that has two opposite ends thereof respectively connected to the positive pin 31 and the external pin 33, a second capacitor 52 that has two opposite ends thereof respectively connected to the external pin 33 and the negative pin 32. In the example shown in FIG. 9, the three Schottky diode chips 2 are connected in series; the electrode pin set 3 comprises the two external pins 33; the snubber circuit 5 comprises the first capacitor 52 that has two opposite ends thereof respectively connected to the positive pin 31 and the first external pin 33, the second capacitor 52 that has two opposite ends thereof respectively connected to the first and second external pins 33, and a third capacitor 52 that has two opposite ends thereof respectively connected to the second external pin 33 and the negative pin 32.

In an alternate form of the present invention, the snubber circuit 5 comprises the resistor 51 and a the capacitor 52 connected in series. In the example shown in FIGS. 1, 3, 4 and 10, the two Schottky diode chips 2 are connected in series; the electrode pin set 3 comprises the one external pin 33; the resistor 51 of the snubber circuit 5 has two opposite ends thereof respectively connected to one end of the positive pin 31 and the capacitor 52; the capacitor 52 has an opposite end thereof connected to the negative pin 32. Thus, the integrated series Schottky diode rectifier can be used in a switching power supply circuit of a switch-mode power supply device that comprises a bridge rectifier and a boost-type power factor correction circuit wherein the input end of the bridge rectifier is connected to AC power supply (such as 115V AC-277V AC); the boost-type power factor correction circuit uses a 600V boost diode to withstand reverse voltage, meeting the power factor correction needs of the boost-type power factor correction circuit in the above-mentioned voltage range.

As stated above, the boost-type power factor correction circuit utilizes the two series-connected Schottky diode chips 2 (such as D1, D2) of identical electrical characteristics to stabilize high reserve voltage. The reasonable resistance value and capacitance value of the can be figured out according to the electrical characteristics of D1. Further, the snubber circuit 5 is connected to the electrode pin set 3 to increase the voltage resistance of D1. Thus, the integrated series Schottky diode rectifier prevents breakdown failure when the first Schottky diode chip 2 receives an excessively high voltage. In actual application, the reverse voltage receives by each Schottky diode chip 2 is just about one half of the reverse voltage a single boost-type diode receives during operation. Further, the Schottky diode chips 2 used in the integrated series Schottky diode rectifier are silicon Schottky diodes that have the characteristics of short reverse recovery time and low reverse recovery loss. Through the voltage division treatment of the series connected the Schottky diode chips 2, the power factor correction circuit can accelerate the switching speed, reduce power loss and improve current rectification efficiency, thereby improving the switching power factor and the utilization of power supply, reducing harmonic pollution, ensuring high-quality power supply and reducing the cost.

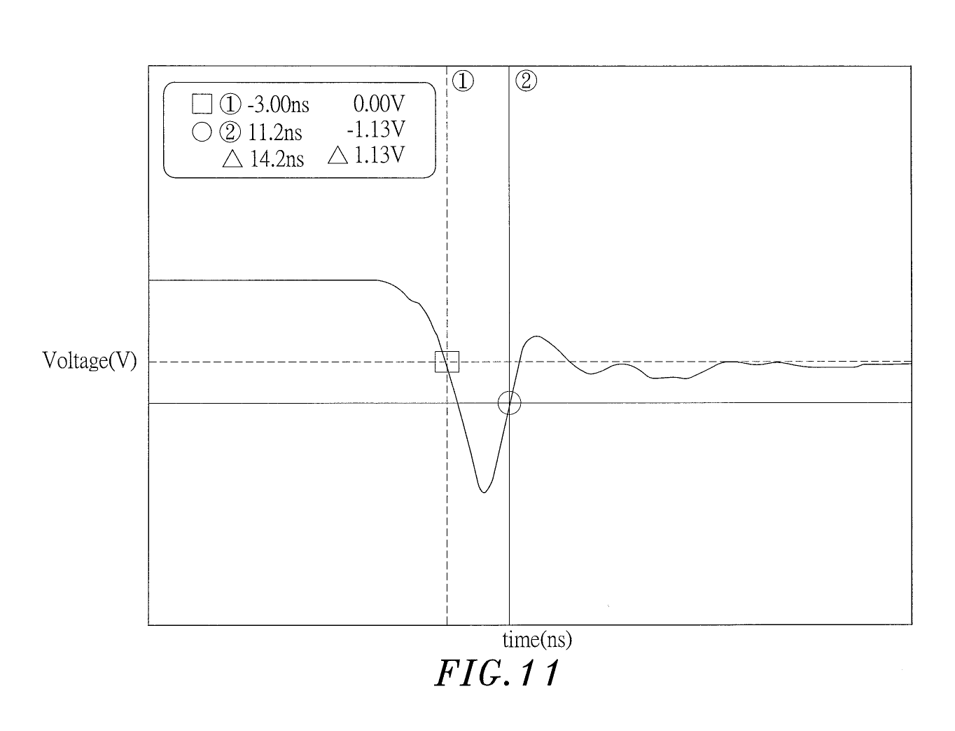

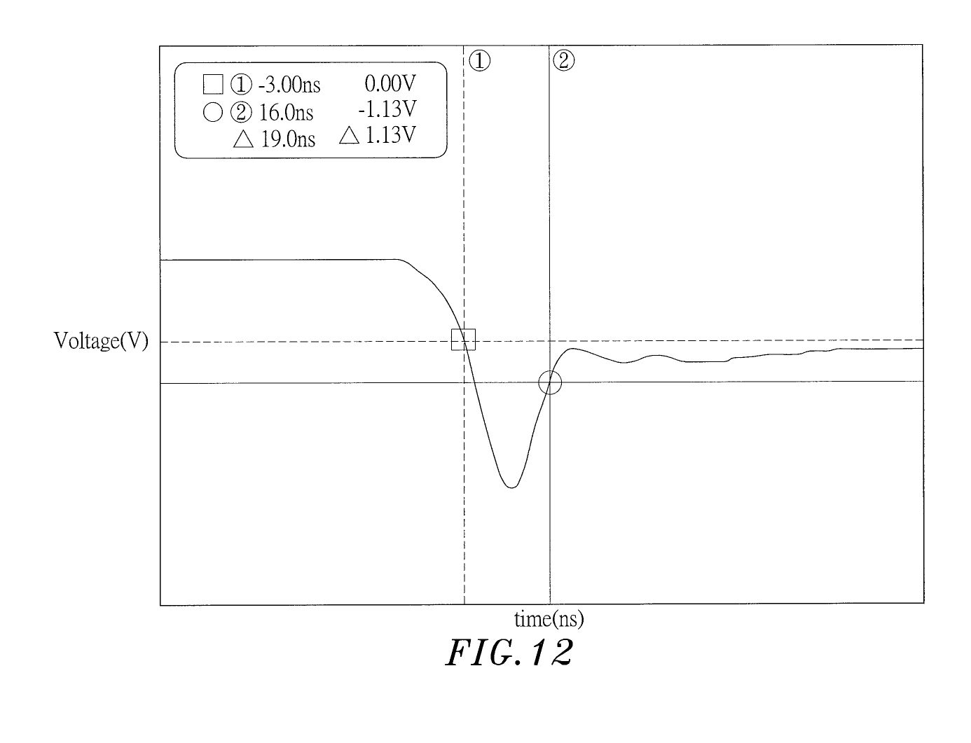

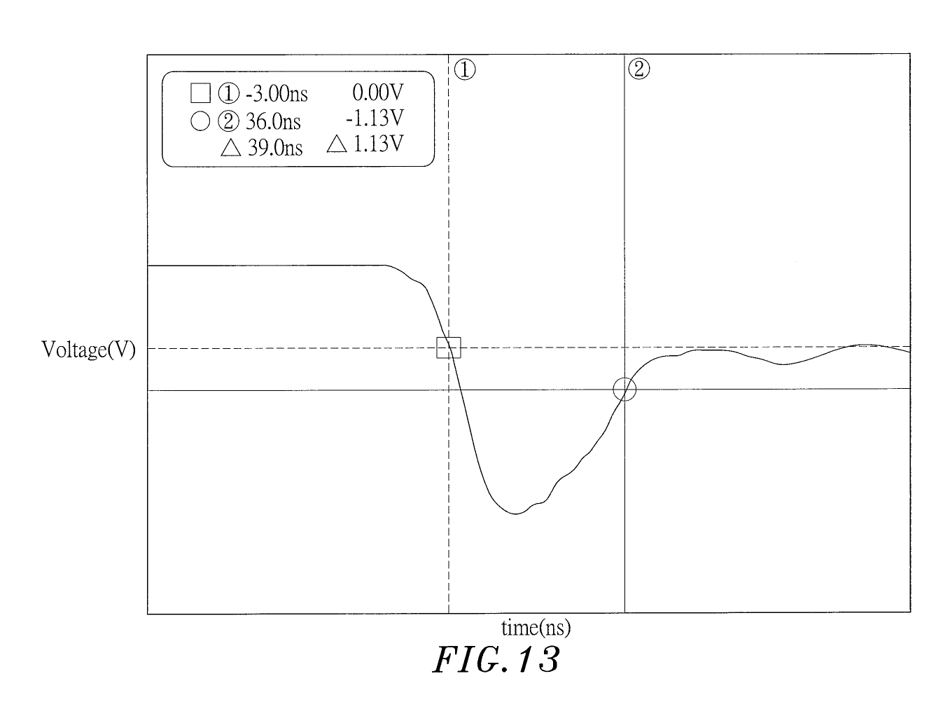

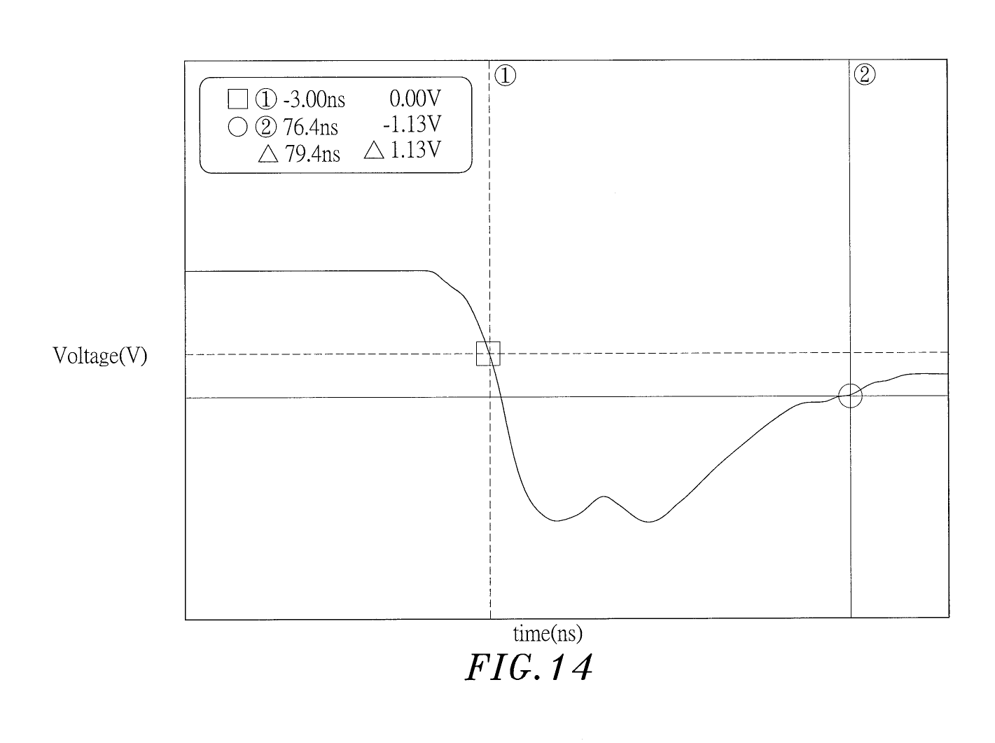

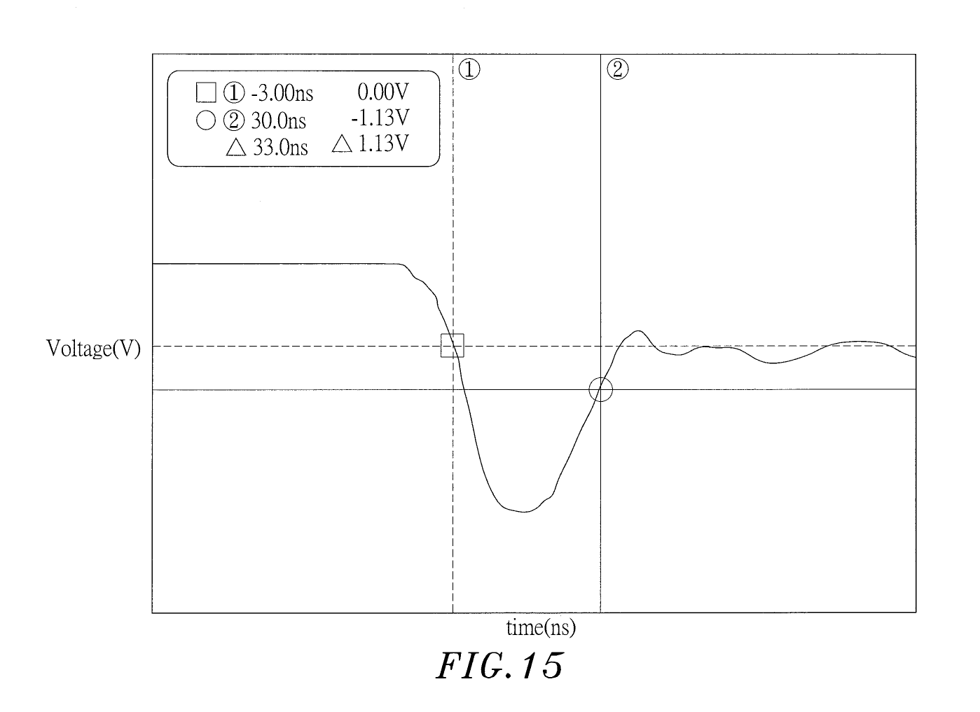

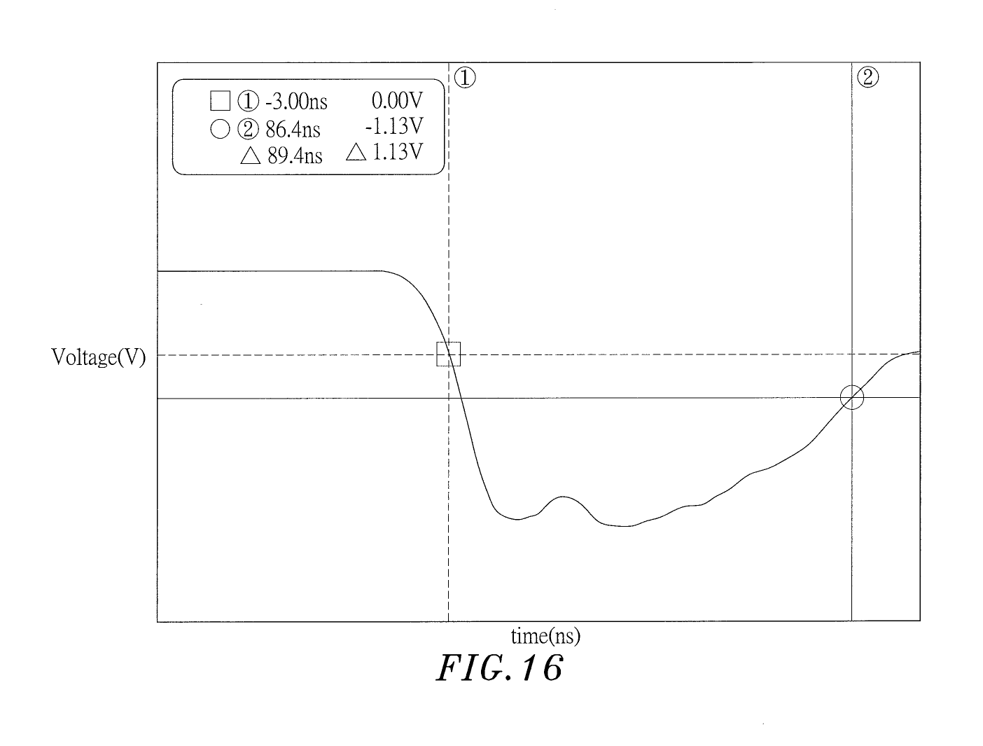

Please refer to FIGS. 11-16, where FIG. 11 is a reverse recovery time and reverse recovery charge waveform chart obtained from a test made on an integrated series Schottky diode rectifier in accordance with the present invention under the room temperature; FIG. 12 is a reverse recovery time and reverse recovery charge waveform chart obtained from a test made on an integrated series Schottky diode rectifier in accordance with the present invention under a high temperature; FIG. 13 is a reverse recovery time and reverse recovery charge waveform chart obtained from a test made on a prior art fast recovery diode-based rectifier under the room temperature; FIG. 14 is a reverse recovery time and reverse recovery charge waveform chart obtained from a test made on the same prior art fast recovery diode-based rectifier under a high temperature; FIG. 15 is a reverse recovery time and reverse recovery charge waveform chart obtained from a test made on another design of prior art fast recovery diode-based rectifier under the room temperature; FIG. 16 is a reverse recovery time and reverse recovery charge waveform chart obtained from a test made on the same another design of prior art fast recovery diode-based rectifier under a high temperature. When using the integrated series Schottky diode rectifier of the present invention in a switching power supply of a power supply device, the Schottky diode chips 2 (such as D1,D2) can be selected to increase the reverse withstand voltage according to different boost type power factor correction circuit operating modes, such as continuous conduction mode (CCM), discontinuous conduction mode (DCM), and critical conduction mode (CRM). For example, the Schottky diode chips 2 that can withstand the same maximum reverse voltage or the Schottky diode chips 2 that can withstand different maximum reverse voltages can be selectively used and connected in series. Under the test conditions of room temperature and high temperature, the integrated series Schottky diode rectifier of the present invention shows the result of shortest reverse recovery time (Trr) and lowest reverse recovery charge (Qrr).

In an example of 90 W switching power supply, the maximum reverse voltage of the power factor correction circuit is 400V, however, in order to maintain a certain margin, a boost diode of withstand voltage 600V is normally used. The integrated series Schottky diode rectifier of the invention uses two series-connected Schottky diode chips 2 (i.e., D1, D2) for voltage division. The value of withstand voltage of the silicon-based Schottky diodes is in the range of 300V˜350V. In actual working, the test results shown in the following Table I can be obtained. When compared with the design of using one single boost diode of withstand voltage 600V (such as MUR460 of Vishay GS, the maximum reverse voltage the first Schottky diode chip 2 of PFCD860 (KTH) of the present invention can withstand is 244V, the maximum reverse voltage the second Schottky diode chip 2 of PFCD860 (KTH) of the present invention can withstand is 56V. According to the test results, a silicon Schottky diode of which the value of withstand voltage is in the range of 200V˜250V can be selected for the second Schottky diode chip 2. From the test results shown in Table I, the reverse recovery time of the two series-connected Schottky diodes of the integrated series Schottky diode rectifier is 13.8 ns, thus, the reverse recovery loss of the integrated series Schottky diode rectifier of the invention is low so that it can reduce high-frequency switching power loss. When compared to silicon carbide Schottky diodes, silicon Schottky diodes are relatively cheaper, and thus, the cost of the power factor correction circuit can be controlled. The reverse recovery time of a rectifier based on one single 600V fast recovery diode is 39.2 ns. The effective power of the switching power supply in the application of the present invention after correction through the power factor correction circuit can be gradually increased as the power of the load changes, so that the power loss can be reduced and the rectification efficiency can be improved, achieving improvement on the power factor of the switching power supply and the utilization of power to reduce the cost.

TABLE I
Electrical characteristics obtained at output power of 90 W switching power supply test.

| | | Vishay GS | | PFCD8 | | |
|---|---|---|---|---|---|---|
| | | MUR460 | | 60 (KTH) | | |
| | Trr (ns) | 39.2 | | 13.8 | | |
| Loading | AC | Efficiency | | | | |
| Ave. | | 91.251% | PF | 91.406% | PF | 0.155% |
| 25% | 115 V | 92.116% | 0.499 | 91.818% | 0.501 | −0.298% |
| | 230 V | 93.235% | 0.425~427 | 93.277% | 0.429~431 | 0.042% |
| 50% | 115 V | 90.980% | 0.968~970 | 91.270% | 0.967~972 | 0.290% |
| | 230 V | 90.858% | 0.918~925 | 91.229% | 0.919~924 | 0.371% |
| 75% | 115 V | 91.001% | 0.986 | 91.094% | 0.985 | 0.093% |
| | 230 V | 91.043% | 0.937 | 91.387% | 0.939 | 0.344% |
| 100% | 115 V | 89.754% | 0.986 | 89.918% | 0.987 | 0.164% |
| | 230 V | 91.02% | 0.958 | 91.254% | 0.960 | 0.234% |

FIGS. 11-16 are waveform charts obtained from tests on an integrated series Schottky diode rectifier of the present invention and two different prior art designs of fast recovery diode-based rectifiers, in which FIGS. 11 and 12 are waveform charts obtained from tests on the integrated series Schottky diode rectifier of the present invention under 25° C. and 125° C.; FIGS. 13 and 14 are waveform charts obtained from tests on MUR460 of Vishay GS under 25° C. and 125° C.; FIGS. 15 and 16 are waveform charts obtained from tests on MUR460 of Yenyo under 25° C. and 125° C. From the waveform charts, we can see that the reverse recovery time of the Schottky diode chip 2 in accordance with the present invention is 14.2 ns at 25° C., 19.0 ns at 125° C.; the reverse recovery time of 600V fast recovery diodes of the prior art designs is in the range of 33.0˜39.0 ns at 25° C., 79.4˜89.4 ns at 125° C. Voltage division treatment through the two series-connected Schottky diode chips 2 of relatively lower voltage resistance and faster recovery time significantly improves the electrical characteristics. Thus, the invention greatly reduces the power loss of the power factor correction circuit and significantly improves the rectification efficiency and the power factor of the switching power supply so that the power supply switching losses, conduction losses and leakage losses can be minimized. Therefore, the integrated series Schottky diode rectifier of the present invention is practical for high frequency, high voltage and high current switching power supply applications, fully in line with the purposes of energy-saving, high efficiency.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. An integrated series Schottky diode rectifier, comprising:
at least two lead frames;
a plurality of Schottky diode chips numbered in a proper order from the first to the last and electrically connected in series, each said Schottky diode chip having a negative electrode located on a back side thereof and electrically connected to said lead frames and a positive electrode located at an opposing front side thereof, the positive electrode of the first said Schottky diode chip having a first conductor bonded thereto, the positive electrode of each of the other said Schottky diode chips having a second conductor bonded thereto, the said second conductor at each said Schottky diode being bridged onto the said lead frame that carries the previous said at least two Schottky diode chips;
an electrode pin set comprising a positive pin, a negative pin and at least one external pin, said positive pin being electrically connected to the said first conductor at the first said Schottky diode chip, said negative pin being electrically connected to the said negative electrode of the last said Schottky diode chip, each said external pin being electrically connected in series between the said second conductors of two adjacent said Schottky diode chips; and
a resin package body molded on said lead frames and wrapped about said Schottky diode chips and said electrode pin set for enabling said positive pin, said negative pin and said external pin to be exposed out of said resin package body.

2. The integrated series Schottky diode rectifier as claimed in claim 1, wherein each said lead frame comprises a flat substrate made of copper or copper alloy, and a radiation fin located at a top side of said flat substrate, said radiation fin having a width larger than said flat substrate.

3. The integrated series Schottky diode rectifier as claimed in claim 1, wherein each said Schottky diode chip is a silicon-based Schottky diode.

4. The integrated series Schottky diode rectifier as claimed in claim 1, wherein said Schottky diode chips have identical electrical characteristics, equivalent to a voltage-series to withstand the same maximum reverse voltage.

5. The integrated series Schottky diode rectifier as claimed in claim 1, wherein said Schottky diode chips have identical electrical characteristics, equivalent to a voltage-series to withstand different maximum reverse voltages.

6. The integrated series Schottky diode rectifier as claimed in claim 1, wherein the said negative electrode of the last said Schottky diode chip has a third conductor bonded thereof, said third conductor being electrically connected to said negative pin of said electrode pin set.

7. The integrated series Schottky diode rectifier as claimed in claim 1, wherein said negative pin of said electrode pin set directly or indirectly extends out of said resin package body from the said lead frame that carries the last said Schottky diode chip.

8. The integrated series Schottky diode rectifier as claimed in claim 1, wherein said negative pin of said electrode pin set directly or indirectly extends out of said resin package body from the at least one said lead frame that carries two adjacent said Schottky diode chips.

9. The integrated series Schottky diode rectifier as claimed in claim 1, further comprising a snubber circuit electrically connected to said electrode pin set, said snubber circuit being connected in parallel to a plurality of said Schottky diode chips at one said leaf frame through at least two kinds of pins among said positive pin, said negative pin and said external pin.

10. The integrated series Schottky diode rectifier as claimed in claim 9, wherein said snubber circuit comprises at least one resistor.

11. The integrated series Schottky diode rectifier as claimed in claim 9, wherein said snubber circuit comprises at least one capacitor.

12. The integrated series Schottky diode rectifier as claimed in claim 9, wherein said snubber circuit comprises at least one resistor and at least one capacitor connected in series.
